(19) United States
(12) Patent Application Publication
(10) Pub. No.: US 2021/0327920 A1
(43) Pub. Date: Oct. 21, 2021

(54) ARRAY SUBSTRATE AND RELATED MANUFACTURING METHOD

(71) Applicant: SHENZHEN CHINA STAR OPTOELECTRONICS SEMICONDUCTOR DISPLAY TECHNOLOGY CO., LTD., Shenzhen (CN)

(72) Inventors: Xingyu ZHOU, Shenzhen (CN); Zhenguo LIN, Shenzhen (CN); Yuanjun HSU, Shenzhen (CN); Poyen LU, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 16/623,411

(22) PCT Filed: Nov. 7, 2019
(86) PCT No.: PCT/CN2019/116120

§ 371 Date: Dec. 17, 2019

(30) Foreign Application Priority Data
Aug. 14, 2019 (CN) 201910747713.7

(51) Int. Cl. H01L 27/12

(52) U.S. Cl. CPC H01L 27/1244; H01L 27/1255; H01L 27/1225; H01L 27/1262; H01L 27/1237

(57) ABSTRACT

An array substrate includes a substrate, a metal light blocking layer positioned on the substrate, a conductive protection layer covering the metal light blocking layer, a buffer layer positioned on the substrate and covering the conductive protection layer, a transistor positioned on the buffer layer and connected to the conductive protection layer, and a pixel electrode connected to the transistor. By utilizing a transparent conductive layer to cover the surface of the copper light blocking layer, the transparent conductive layer becomes a protection layer on the copper layer to protect it from being oxidized and diffused. It also reduces the damage on the copper layer during the etching process and reduces the stripping risk of the copper layer.

### FIELD OF THE INVENTION

The present invention relates to the display field, and more particularly to an array substrate and its related manufacturing method.

### BACKGROUND

A conventional oxide TFT substrate with a self-aligned gate structure often adopts copper (Cu) as a light blocking layer to alleviate the wiring risk of other metal layers. However, copper has an oxidation issue.

### SUMMARY

One objective of an embodiment of the present invention is to provide an array substrate and its related manufacturing method to solve the above issue.

According to an embodiment of the present invention, an array substrate is disclosed. The array substrate comprises a substrate, a metal light blocking layer positioned on the substrate, a conductive protection layer covering the metal light blocking layer, a buffer layer positioned on the substrate and covering the conductive protection layer, a transistor positioned on the buffer layer and connected to the conductive protection layer, and a pixel electrode connected to the transistor.

Optionally, a material of the metal light blocking layer comprises at least one of molybdenum, aluminum, copper, titanium or an alloy.

Optionally, a thickness of the metal light blocking layer is 50-1000 nm.

Optionally, the array substrate further includes a first electrode, forming a storage capacitor with the pixel electrode. The first electrode, the pixel electrode and the conductive protection layer are all implemented with a transparent conductive material.

Optionally, the transistor includes an active layer positioned on the buffer layer, an N+ semiconductor layer positioned in the active layer, a channel positioned in the active layer, a gate insulating layer positioned on the active layer, a gate metal layer positioned on the gate insulating layer, an interlayer insulating layer positioned on the gate metal layer, a first contact hole passing through the interlayer insulating layer, a second contact hole passing through the interlayer insulating layer and the buffer layer, and an output stage which is positioned on the interlayer insulating layer and is connected to the N+ semiconductor layer and connected to the conductive protection layer via the second contact hole.

According to an embodiment of the present invention, a manufacturing method of an array substrate is disclosed. The method comprises: forming a metal blocking layer on a substrate; depositing a first transparent conductive layer on the substrate, and etching the first transparent conductive layer to form a first electrode and a conductive protection layer, wherein the conductive protection layer covers the metal light blocking layer; forming a buffer layer on the substrate to cover the first electrode and the conductive protection layer; forming a transistor on the buffer layer; and forming a pixel electrode on the transistor; wherein the first electrode and the pixel electrode forms a storage capacitor.

Optionally, a material of the metal light blocking layer comprises at least one of molybdenum, aluminum, copper, titanium or an alloy.

Optionally, a thickness of the metal light blocking layer is 50-1000 nm.

Optionally, the method further includes: etching a conductive material layer deposited on the buffer layer to form an active layer; depositing an insulating material layer and a metal material layer on the buffer layer; etching the metal material layer to form a gate metal layer; utilizing the gate metal layer as a mask to etch the insulating material layer to form a gate insulating layer; performing an ionizing process on the active layer to form a N+ semiconductor layer and a channel of the transistor; etching an interlayer insulating layer deposited on the buffer layer and the buffer layer to form a first contact hole and a second contact hole, wherein the first contact hole passes through the interlayer insulating layer and the second contact hole passes through the interlayer insulating layer and the buffer layer; and forming an output stage of the transistor such that the output stage connects to the N+ semiconductor layer via the first contact hole and connects to the conductive protection layer via the second contact hole.

Optionally, the method further includes etching a planarization layer deposited on the interlayer insulating layer to form a third contact hole, and forming the pixel electrode such that the pixel electrode connects to the output stage via the third contact hole.

In contrast to the conventional art, an embodiment of the present invention utilizes a transparent conductive layer to cover the surface of the copper light blocking layer. This transparent conductive layer becomes a protection layer on the copper layer to protect it from being oxidized and diffused. It also reduces the damage on the copper layer during the etching process and reduces the stripping risk of the copper layer.

These and other features, aspects and advantages of the present disclosure will become understood with reference to the following description, appended claims and accompanying figures.

### BRIEF DESCRIPTION OF THE DRAWINGS

To describe the technical solutions in the embodiments of this application more clearly, the following briefly introduces the accompanying drawings required for describing the embodiments. Apparently, the accompanying drawings in the following description show merely some embodiments of this application, and a person of ordinary skill in the art may still derive other drawings from these accompanying drawings without creative efforts.

FIG. 1 is a diagram of an array substrate according to an embodiment of the present invention.

FIG. 2 is a flow chart of manufacturing an array substrate according to an embodiment of the present invention.

FIGS. 3-15 are diagrams showing the steps of manufacturing an array substrate according to an embodiment of the present invention.

### DETAILED DESCRIPTION OF PREFERRED EMBODIMENTS

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented and the spatially relative descriptors used herein interpreted accordingly.

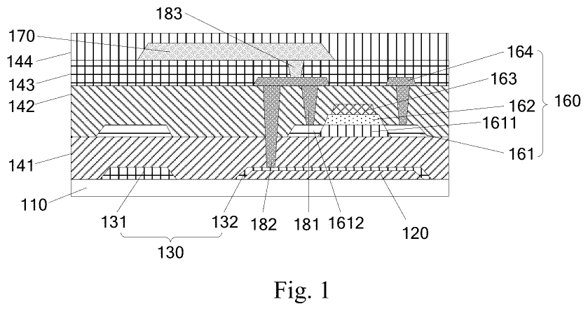

Please refer to FIG. 1. FIG. 1 is a diagram of an array substrate according to an embodiment of the present invention. As shown in FIG. 1, an array substrate 10 comprises a substrate 110, a metal light blocking layer 120, a first electrode 131, a conductive protection layer 132, a buffer layer 141, a transistor 160, an interlayer insulating layer 142, a passivation layer 143, a pixel electrode 170 and a planarization layer 144.

The material of the metal light blocking layer 120 comprises at least one of molybdenum, aluminum, copper, titanium or an alloy. The thickness of the metal light blocking layer 120 is 50-1000 nm.

The conductive protection layer 132 covers the metal light blocking layer 120. The conductive protection layer 132 is a transparent conductive layer. The material of the transparent conductive layer could be Indium Tin Oxide (ITO), Indium Zinc Oxide (IZO) or a combination of ITO and IZO. The conductive protection layer 132 could prevent copper from being oxidized and diffused or being damaged during the later etching process. The thickness of the conductive protection layer 132 is 20-200 nm. The first electrode 131 is positioned on the substrate 110. The first electrode 131 and the conductive protection layer 132 are both transparent conductive layers. The first electrode 131 and the conductive protection layer 132 could be formed at the same time. The first electrode 131 has a thickness of 20-200 nm.

The buffer layer 141 is positioned on the first electrode 131. The buffer layer 141 could block the moisture and impurity to prevent the moisture and impurity from being diffused into the substrate 110, the metal light blocking layer 120, the first electrode 131 and the conductive protection layer 132. In addition, the buffer layer 141 could be used as a planarization layer such that a later planarization process step could be eliminated to reduce the cost. The buffer layer 131 could be a film of at least one of silicon oxide (SiOx), silicon nitride (SiNx), silicon oxynitride (SiOxNy), aluminum oxide (AlOx), aluminum nitride (AlNx) and other inorganic materials. The buffer layer 141 has a thickness of 100-500 nm.

The transistor 160 comprises an active layer 161, a gate insulating layer 162, a gate metal layer 163 and an output stage 164. The active layer 161 is positioned on the buffer layer 141. The active layer 161 is one of IGZO, IZTO or IGZTO. The active layer 161 has a thickness of 10-100 nm. The semiconductor active layer 161 could be formed by crystallizing an amorphous silicon into a poly-silicon. Specifically, in order to crystallize the amorphous silicon, a RTA process, an ELA process, an SPC process, and an MIC process, an MILC process or an SLS process could be used. In addition, an ionizing doping technique is used to perform an ion doping process on the active layer 161 such that the area not covered by the gate metal layer 163 and the gate insulating layer 162 forms a N+ semiconductor layer 1612 and thus has a better conductivity. The area covered by the gate metal layer 163 and gate insulating layer 162 remains its semiconductor characteristic and becomes the channel 1611 of the transistor 160.

The gate insulating layer 162 is positioned on the active layer 161. The gate insulating layer 162 could be implemented with silicon oxide, silicon nitride, metal oxide or other inorganic materials and could be a single layer structure or a multi-layer structure. The gate insulating layer 162 has a thickness of 100-300 nm. The gate metal layer 163 is positioned on the gate insulating layer 162. The gate metal layer 163 could comprise a single layer structure or multi-layer structure comprising one of gold (Au), silver (Ag), copper (Cu), molybdenum (Mo), nickel (Ni), platinum (Pt), aluminum (Al), chromium (Cr), aluminum-neodymium (Al—Rd) alloy or molybdenum-tungsten (Mo—W) alloy. The gate metal layer 163 has a thickness of 200-1000 nm.

The interlayer insulating layer 142 is positioned on the gate metal layer 163. The interlayer insulating layer 142 could be implemented with silicon oxide, silicon nitride or other insulating inorganic material. The interlayer insulating layer 142 has a thickness of 200-1000 nm. The output stage 164 is positioned on the interlayer insulating layer 142. The output stage 164 could comprise a single layer structure or multi-layer structure comprising one of gold (Au), silver (Ag), copper (Cu), molybdenum (Mo), nickel (Ni), platinum (Pt), aluminum (Al), chromium (Cr), aluminum-neodymium (Al—Rd) alloy or molybdenum-tungsten (Mo—W) alloy. The output stage 164 has a thickness of 200-1000 nm.

A contact hole 181 is formed to passing through the interlayer insulating layer 142. The first contact hole 181 vertically extends to the top of active layer 161. The first contact hole 181 is filled and covered by the source/drain metal layer (the output stage 164). The second contact hole 182 passes through the interlayer insulating layer 142 and the buffer layer 141. The second contact hole vertically extends to the top of the conductive protection layer 132. The second contact hole 182 is filled and covered by the source/drain metal layer (the output stage 164).

The passivation layer 143 is positioned on the output stage 164. The passivation layer is a silicon oxide layer, a silicon nitride layer or their combination. The passivation layer 143 has a thickness of 100-500 nm. The third contact hole 183 is in the passivation layer 143 and vertically extends to the output stage 164. The pixel electrode 170 is positioned on the passivation layer 143. The third contact hole 183 is filled and covered by the pixel electrode 170. The material of the pixel electrode 170 could be ITO, IZO or their combination. The planarization layer 144 is positioned on the pixel electrode 170. The planarization layer 144 could be implemented with PI, Polyamide, BCB, Acrylic resin, Phenol formaldehyde resin or other organic materials. The planarization layer 144 has a thickness of 0.5-2 microns.

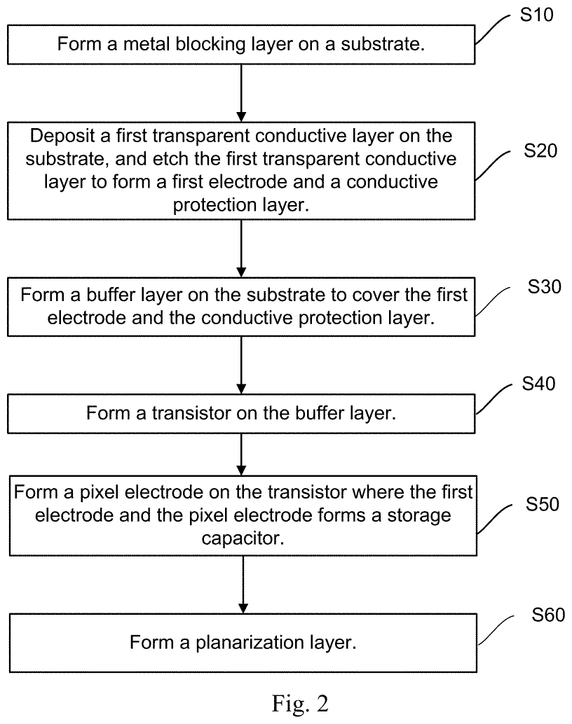

The above-mentioned array substrate could be used to drive LCD, OLED, QLED, or μLED. Please refer to FIG. 2. A manufacturing method of an array substrate is disclosed. The method comprises the steps below: S10: forming a metal blocking layer 120 on a substrate 100; S20: depositing a first transparent conductive layer 130 on the substrate 100, and etching the first transparent conductive layer 130 to form a first electrode 131 and a conductive protection layer 132, wherein the conductive protection layer 132 covers the metal light blocking layer 120; S30: forming a buffer layer 141 on the substrate 110 to cover the first electrode 131 and the conductive protection layer 132; S40: forming a transistor 160 on the buffer layer 141; S50: forming a pixel electrode 170 on the transistor 160 wherein the first electrode 131 and the pixel electrode 170 forms a storage capacitor; and S60: forming a planarization layer 144.

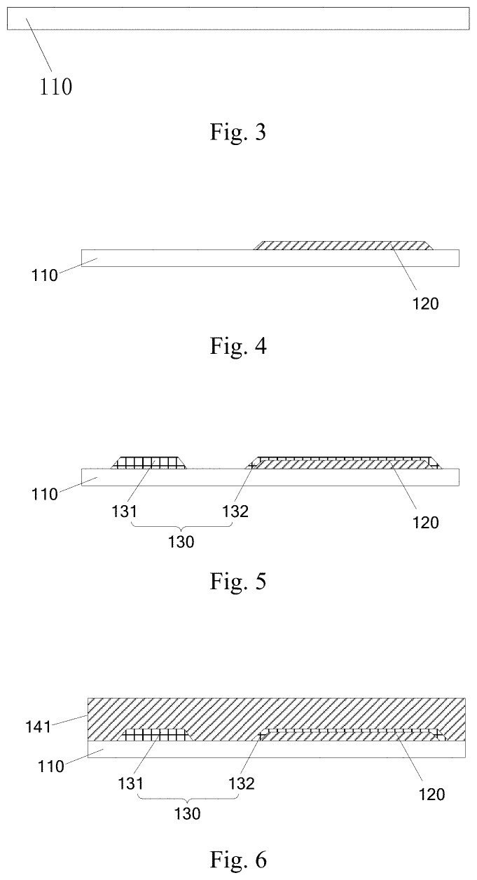

Please refer to FIG. 3 and FIG. 4. The metal light blocking layer 120 is deposited on the substrate 110 and is then etched to form a pattern. The material of the metal light blocking layer 120 could be copper (Cu), molybdenum (Mo), aluminum (Al), titanium (Ti) or an alloy of some of them. In this embodiment, the metal light block layer 120 is implemented with copper as an example, but not a limitation. The metal light blocking layer 120 has a thickness of 500-10000 A. This structure could alleviate the wiring risk of other metal layers.

Please refer to FIG. 5. As shown in FIG. 5, the first transparent conductive layer 130 is deposited on the metal light blocking layer 120 and is then etched to form a pattern. In this embodiment, the part of the first transparent conductive layer 130 covering the surface of the metal light blocking layer 120 becomes the conductive protection layer 132. The conductive protection layer 132 could prevent copper from being oxidized or being diffused or etching damages during later etching processes. The other part of the first transparent conductive layer 130 covering the substrate 120 becomes the first electrode 131. The first electrode 130 has a thickness of 20-200 nm.

Please refer to FIG. 6. As shown in FIG. 6, the buffer layer 141 is formed on the first transparent conductive layer 130. The buffer layer 141 is used as a blocking layer to block moisture or impurity to prevent the moisture and impurity from being diffused into the substrate 110, the metal light blocking layer 120 and the first electrode 130. Furthermore, the buffer layer 141 is used as a planarization layer such that a later planarization process could be eliminated to save cost. The buffer layer 131 could be a film of at least one of silicon oxide (SiOx), silicon nitride (SiNx), silicon oxynitride (SiOxNy), aluminum oxide (AlOx), aluminum nitride (AlNx) and other inorganic materials. The buffer layer 141 has a thickness of 100-500 nm.

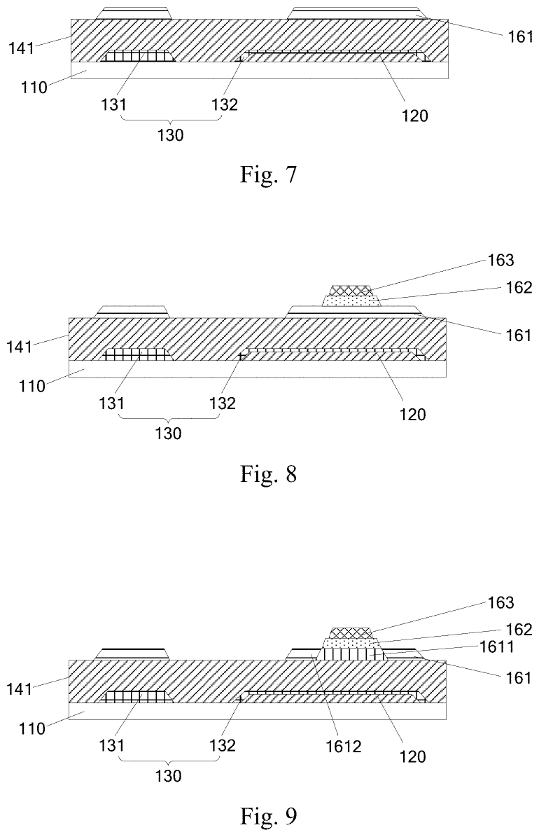

Please refer to FIG. 7. As shown in FIG. 7, the active layer 161 is formed on the buffer layer 141. The semiconductor active layer 161 could be formed by crystallizing an amorphous silicon into a poly-silicon. Specifically, in order to crystallize the amorphous silicon, a RTA process, an ELA process, an SPC process, and an MIC process, an MILC process or an SLS process could be used.

Please refer to FIG. 8. As shown in FIG. 8, the insulating material layer and the metal material layer are deposited on the buffer layer 141. Then, the metal material layer is etched to form the gate metal layer 163. And then, the gate metal layer 163 is used as mask to etch the insulating material layer to form the gate insulating layer 162.

Please refer to FIG. 9. As shown in FIG. 9, the ionizing process is performed on the active layer 161 such that the area not covered by the gate metal layer 163 and the gate insulating layer 162 forms a N+ semiconductor layer 1612 and thus has a better conductivity. The area covered by the gate metal layer 163 and gate insulating layer 162 remains its semiconductor characteristic and becomes the channel 1611 of the transistor 160.

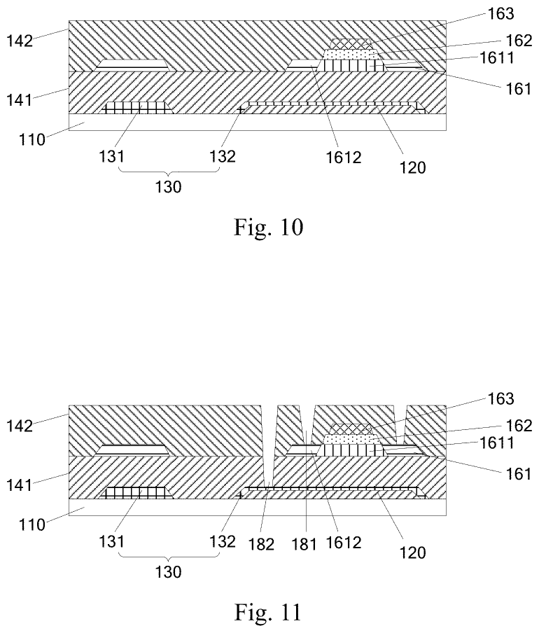

Please refer to FIG. 10. As shown in FIG. 10, the interlayer insulating layer 142 is formed on the gate metal layer 163.

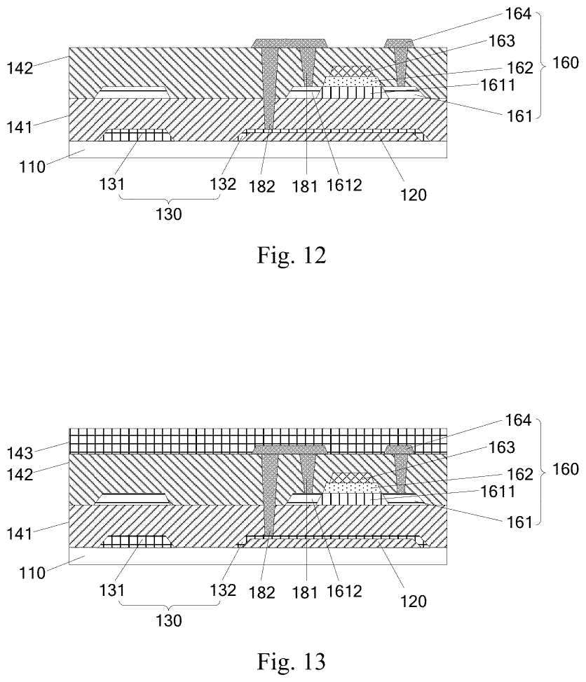

Please refer to FIG. 11 and FIG. 12. As shown in FIGS. 11 and 12, the etching process is performed to form the first contact hole 181 and the second contact hole 182. The first contact hole 181 is positioned in the interlayer insulating layer 142. The first contact hole 181 vertically extends to the N+ semiconductor layer 1612. The second contact hole 182 passes through the interlayer insulating layer 142 and the buffer layer 141. The second contact hole vertically extends to the top of the conductive protection layer 132. Then, the output stage 164 (the source/drain metal layer) is deposited on the interlayer insulating layer 142. In this way, the output stage 164 touches the N+ semiconductor 1612 and the conductive protection layer 132 via the first contact hole 181 and the second contact hole 182. The output stage 164 could comprise one of copper (Cu), molybdenum (Mo), aluminum (Al), titanium (Ti) or an alloy of some of them. The output stage 164 has a thickness of 200-1000 nm.

Please refer to FIG. 13. As shown in FIG. 13, the passivation layer 143 is deposited on the output stage 164. The passivation layer 143 is a silicon oxide layer, a silicon nitride layer or their combination. The passivation layer 143 has a thickness of 100-500 nm.

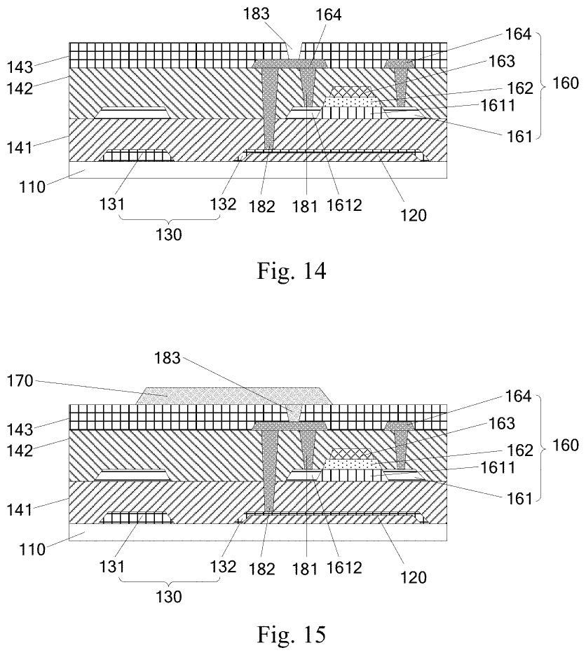

Please refer to FIG. 14, the passivation layer 143 is etched to form the third contact hole 183. The third contact hole 183 is in the passivation layer 143 and vertically extends to the top surface of the output stage.

Please refer to FIG. 3 and FIG. 15. As shown in the FIGS. 3 and 15, the pixel electrode 170 is deposited on the passivation layer. The material of the pixel electrode 170 could be ITO, IZO or their combination. Then, the planarization layer 144 is deposited on the pixel electrode 170. The planarization layer 144 is positioned on the pixel electrode 170. The planarization layer 144 could be implemented with PI, Polyamide, BCB, Acrylic resin, Phenol formaldehyde resin or other organic materials. The planarization layer 144 has a thickness of 0.5-2 microns.

From the above, a person having ordinary skills in the art could understand that a benefit of an embodiment of the present invention is to utilize a transparent conductive layer to cover the surface of the copper light blocking layer. This transparent conductive layer becomes a protection layer on the copper layer to protect it from being oxidized and diffused. It also reduces the damage on the copper layer during the etching process and reduces the stripping risk of the copper layer.

While the embodiments of the present disclosure have been shown and described above, it is to be understood that the above embodiments are exemplary and are not to be construed as limiting the present disclosure. One of ordinary skill in the art may make variations, modifications, substitutions and alterations to the above embodiments within the scope of the present disclosure.

### INDUSTRIAL APPLICABILITY

The subject matter of the present disclosure can be manufactured and used in an industry, thereby meeting industrial applicability.

What is claimed is:

1. An array substrate comprising:
a substrate;
a metal light blocking layer, positioned on the substrate;
a conductive protection layer, covering the metal light blocking layer;
a buffer layer, positioned on the substrate and covering the conductive protection layer;
a transistor, positioned on the buffer layer and connected to the conductive protection layer; and
a pixel electrode, connected to the transistor.

2. The array substrate of claim 1, wherein a material of the metal light blocking layer comprises at least one of molybdenum, aluminum, copper, titanium or an alloy.

3. The array substrate of claim 1, wherein a thickness of the metal light blocking layer is 50-1000 nm.

4. The array substrate of claim 1, further comprising:
a first electrode, forming a storage capacitor with the pixel electrode;
wherein the first electrode, the pixel electrode and the conductive protection layer are all implemented with a transparent conductive material.

5. The array substrate of claim 1, wherein the transistor comprises:
an active layer, positioned on the buffer layer;
an N+ semiconductor layer, positioned in the active layer;
a channel, positioned in the active layer;
a gate insulating layer, positioned on the active layer;
a gate metal layer, positioned on the gate insulating layer;
an interlayer insulating layer; positioned on the gate metal layer;
a first contact hole, passing through the interlayer insulating layer;
a second contact hole, passing through the interlayer insulating layer and the buffer layer; and
an output stage, positioned on the interlayer insulating layer, connected to the N+ semiconductor layer and connected to the conductive protection layer via the second contact hole.

6. A manufacturing method of an array substrate, the method comprising:
forming a metal blocking layer on a substrate;
depositing a first transparent conductive layer on the substrate, and etching the first transparent conductive layer to form a first electrode and a conductive protection layer, wherein the conductive protection layer covers the metal light blocking layer;
forming a buffer layer on the substrate to cover the first electrode and the conductive protection layer;
forming a transistor on the buffer layer; and
forming a pixel electrode on the transistor;
wherein the first electrode and the pixel electrode form a storage capacitor.

7. The method of claim 6, wherein a material of the metal light blocking layer comprises at least one of molybdenum, aluminum, copper, titanium or an alloy.

8. The method of claim 6, wherein a thickness of the metal light blocking layer is 50-1000 nm.

9. The method of claim 6, further comprising:
etching a conductive material layer deposited on the buffer layer to form an active layer;
depositing an insulating material layer and a metal material layer on the buffer layer;
etching the metal material layer to form a gate metal layer;
utilizing the gate metal layer as a mask to etch the insulating material layer to form a gate insulating layer;
performing an ionizing process on the active layer to form a N+ semiconductor layer and a channel of the transistor;
etching an interlayer insulating layer deposited on the buffer layer and the buffer layer to form a first contact hole and a second contact hole, wherein the first contact hole passes through the interlayer insulating layer and the second contact hole passes through the interlayer insulating layer and the buffer layer; and
forming an output stage of the transistor such that the output stage connects to the N+ semiconductor layer via the first contact hole and connects to the conductive protection layer via the second contact hole.

10. The method of claim 9, further comprising:
etching a planarization layer deposited on the interlayer insulating layer to form a third contact hole; and
forming the pixel electrode such that the pixel electrode connects to the output stage via the third contact hole.
